(19) United States
(12) Patent Application Publication
(10) Pub. No.: US 2015/0083586 A1
(43) Pub. Date: Mar. 26, 2015

(54) DEPOSITION APPARATUS

(71) Applicant: CANON ANELVA CORPORATION, Kawasaki-shi (JP)

(72) Inventors: Teruaki ONO, Chofu-shi (JP); Masahiro SHIBAMOTO, Hachioji-shi (JP)

(73) Assignee: CANON ANELVA CORPORATION, Kawasaki-shi (JP)

(21) Appl. No.: 14/484,739

(22) Filed: Sep. 12, 2014

(30) Foreign Application Priority Data
Sep. 26, 2013 (JP) 2013-200493

(51) Int. Cl. H01J 37/32

(52) U.S. Cl. CPC H01J 37/32669
USPC 204/298.41

(57) ABSTRACT

A deposition apparatus comprises a source unit having a function of generating a plasma by an arc discharge; and a filter unit configured to transport the plasma generated by the source unit toward a material to be deposited, wherein the filter unit includes a duct configured to transport the plasma, a magnetic field formation unit configured to form, in the duct, a magnetic field for transporting the plasma, and a magnetic field bending unit configured to generate a magnetic force for bending the magnetic field formed by the magnetic field formation unit.

### BACKGROUND OF THE INVENTION

1. Field of the Invention

The present invention relates to a deposition apparatus using an arc discharge.

2. Description of the Related Art

As a method of forming a protection film for a medium such as a hard disk, there is a CVD method using a reactive gas such as C₂H₂ or C₂H₄. Recently, a thinner protection film of carbon or the like deposited on a magnetic recording layer is required to further shorten the head flying height and the spacing distance between a magnetic read head and the magnetic recording layer of a medium, and improve the drive characteristic.

However, the limitation of the thickness of the carbon protection film deposited by CVD is said to be 2 to 3 nm owing to its characteristic. As a technique replacing CVD, attention has been paid to a film deposition method (vacuum arc deposition) which uses an arc discharge and can form a thinner carbon protection film. Vacuum arc deposition can deposit a harder carbon protection film with a lower hydrogen content in comparison with CVD, and has the possibility of decreasing the film thickness to about 1 nm.

For example, Japanese Patent Laid-Open No. 2010-202899 discloses a film deposition apparatus including a striker configured to form an arc spot on a target and emit target ions and electrons by an arc discharge, an anode unit configured to maintain an arc, an anode coil configured to form a flow of electrons between targets, and a filter unit configured to guide target ions and electrons to a process chamber.

At an arc spot (location where an arc is generated), electrons and ions are generated. In addition, a liquid or solid target material also emerges, which is called a droplet. In general, the droplet needs to be prevented from reaching a material to be deposited and entering a film. Various methods for implementing this have been proposed.

Examples are a method of bending a plasma path twice or more so that a droplet traveling from a target does not reach a substrate (for example, Japanese Patent Laid-Open No. 2010-202899 and U.S. Pat. No. 6,031,239), and a method of narrowing part of a plasma path to remove a droplet (for example, Japanese Patent No. 4889957).

It is generally considered that there are droplets in the micron size or larger and droplets in the submicron size. Droplets in the micron size or larger have a size of several μm or larger, and reach a material to be deposited while mostly repeating collision and reflection by the wall surface of a plasma path. As for droplets in the micron size or larger, the above-described problem can be substantially solved by devising the shape of an internal shield.

Submicron-size droplets have a size of several nm to several μm or less. Some such droplets are charged and attracted by a plasma, or tangled in lines of magnetic force, and reach a material to be deposited. The most effective means for removing submicron-size droplets are considered to be, a method of bending a plasma path twice or more and shaking droplets off a plasma or lines of magnetic force by centrifugal force, and a method of applying, to the wall surface of a plasma path, a potential at which droplets are attracted, thereby removing the droplets.

However, the structure in which the plasma path is bent twice or more complicates the shape and makes maintenance difficult. In the method of applying a potential, the deposition rate decreases. Thus, there is room for improvement.

### SUMMARY OF THE INVENTION

The present inventors have conceived a new droplet removal method by paying attention to the facts that bending a plasma path twice or more is a very effective means for removing submicron-size droplets and the plasma is transported along lines of magnetic force. According to this method, permanent magnets are helically arranged at a linear magnetic field generation means, or a coil having a central axis at a position decentered from the central axis of the magnetic field generation means is arranged to form the magnetic field of a plasma path into not a linear shape but a helical shape. Centrifugal force always acts on electrons, ions, and droplets passing through the helical path, thereby removing only heavy droplets.

The present invention has been made in consideration of the aforementioned problems, and realizes a deposition apparatus which has a simpler shape and good maintainability and can remove droplets without decreasing the deposition rate.

In order to solve the aforementioned problems, the present invention provide a deposition apparatus comprising: a source unit having a function of generating a plasma by an arc discharge; and a filter unit configured to transport the plasma generated by the source unit toward a material to be deposited, wherein the filter unit includes a duct configured to transport the plasma, a magnetic field formation unit configured to form, in the duct, a magnetic field for transporting the plasma, and a magnetic field bending unit configured to generate a magnetic force for bending the magnetic field formed by the magnetic field formation unit.

According to the present invention, droplets can be removed by shaking off, by centrifugal force, charged droplets passing through a plasma path. Also, the apparatus arrangement has a relatively simple shape, and the maintainability can be improved.

Further features of the present invention will become apparent from the following description of exemplary embodiments (with reference to the attached drawings).

### BRIEF DESCRIPTION OF THE DRAWINGS

FIG. 1 is a sectional view showing the schematic arrangement of a film deposition apparatus according to an embodiment of the present invention;

FIG. 2 is a sectional view showing the arrangement of the filter unit of the film deposition apparatus in FIG. 1;

FIGS. 3A and 3B are side views showing the arrangement of the source unit of the film deposition apparatus in FIG. 1 when viewed from two directions;

FIG. 3C is a sectional view taken along a line I-I in FIG. 3B;

FIG. 4 is a block diagram showing the schematic arrangement of the power supply system of the film deposition apparatus according to the embodiment;

FIG. 5 is a block diagram showing the schematic arrangement of the control system of the film deposition apparatus according to the embodiment;

FIG. 6 is a view showing the arrangement of the permanent magnets of the filter unit according to the embodiment; and

FIGS. 7A to 7C are views showing a simple magnetic field simulation result of the filter unit according to the embodiment.

### DESCRIPTION OF THE EMBODIMENTS

An exemplary embodiment of the present invention will now be described in detail with reference to the accompanying drawings. Note that the constituent elements described in the embodiment are merely examples. The technical scope of the present invention is determined by the scope of claims and is not limited by the following individual embodiment.

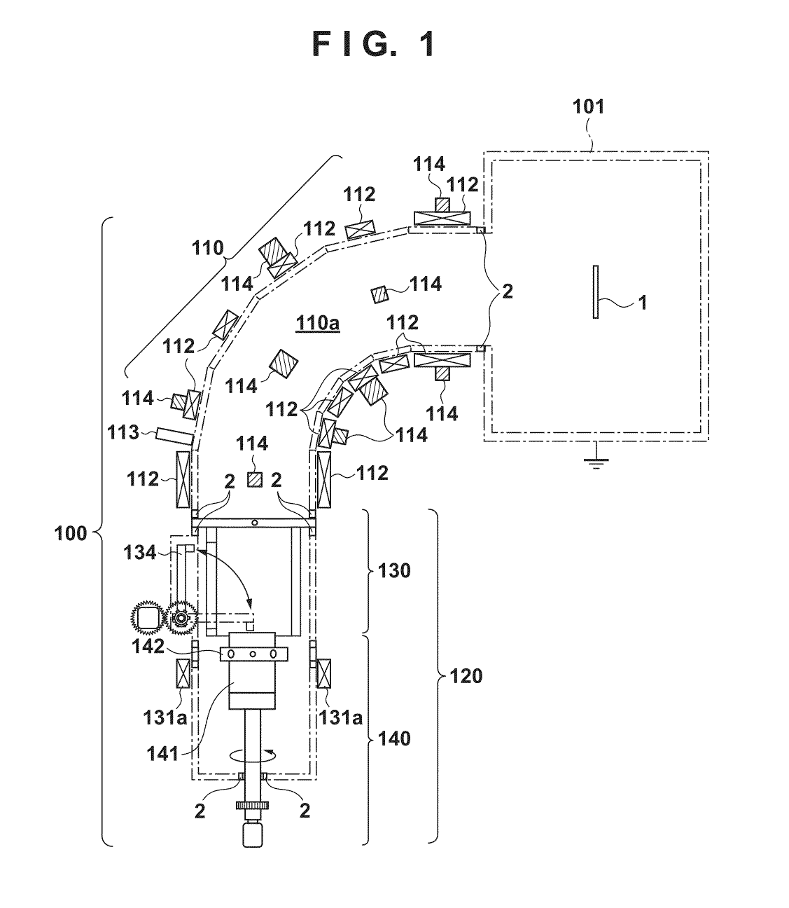

An embodiment in which a film deposition apparatus according to the present invention is applied to a film deposition apparatus configured to form a protection film on a substrate serving as a material to be deposited by using vacuum arc deposition.

<Apparatus Arrangement> First, the arrangement of the film deposition apparatus according to the embodiment of the present invention will be explained with reference to FIG. 1 to FIGS. 3A to 3C.

In FIG. 1, a film deposition apparatus 100 according to the embodiment includes a process chamber 101 which loads a substrate 1 on which a 3-nm or less protection film of a target material (for example, carbon) is deposited, a filter unit 110 coupled to the process chamber 101 so as to communicate inside, and a source unit 120 coupled to the filter unit 110 so as to communicate inside. Insulating members 2 are arranged at the coupling portions between the process chamber 101 and the filter unit 110 and between the filter unit 110 and the source unit 120 so that an electrically insulating state is held at each portion. Although carbon is used as the target material, the target material is not limited to carbon and for example, Ti or TiN is also usable.

The filter unit 110 includes one or more transport pipes 111 which form a guide path (duct) 110a bent at 90° and hold the inside of the guide path 110a in a vacuum state, filter coils 112 which form a magnetic field for transporting electrons and target ions on the atmospheric side or vacuum side of the transport pipes 111, and a magnetic field formation unit such as a permanent magnet. The guide path 110a is constituted by coupling one or more transport pipes 111. The filter coil 112 is arranged all around the outer side (atmospheric side) of each transport pipe 111. The guide path 110a guides, toward the substrate 1, electrons and target ions generated by the source unit 120, and removes a carbon particle of a large particle size serving as a particle. A voltage application unit such as a voltage application terminal 113 is arranged on the transport pipe 111. When there are two or more transport pipes 111, each transport pipe 111 can be set to an electrically conductive state or can be set to an electrically insulating state by arranging an insulating member at each coupling portion. Either state can be selected.

In the embodiment, six pairs of (12) permanent magnets 114 are arranged as magnetic field bending units on the outer surface of the transport pipes 111 on the atmospheric side. The positional relationship between the filter unit 110 and each permanent magnet 114 will be described later.

The source unit 120 includes an anode unit 130, cathode target unit 140, and anode coil 131a. The source unit 120 maintains an arc discharge by maintaining an electron current or ion current between the anode unit 130 and the cathode target unit 140.

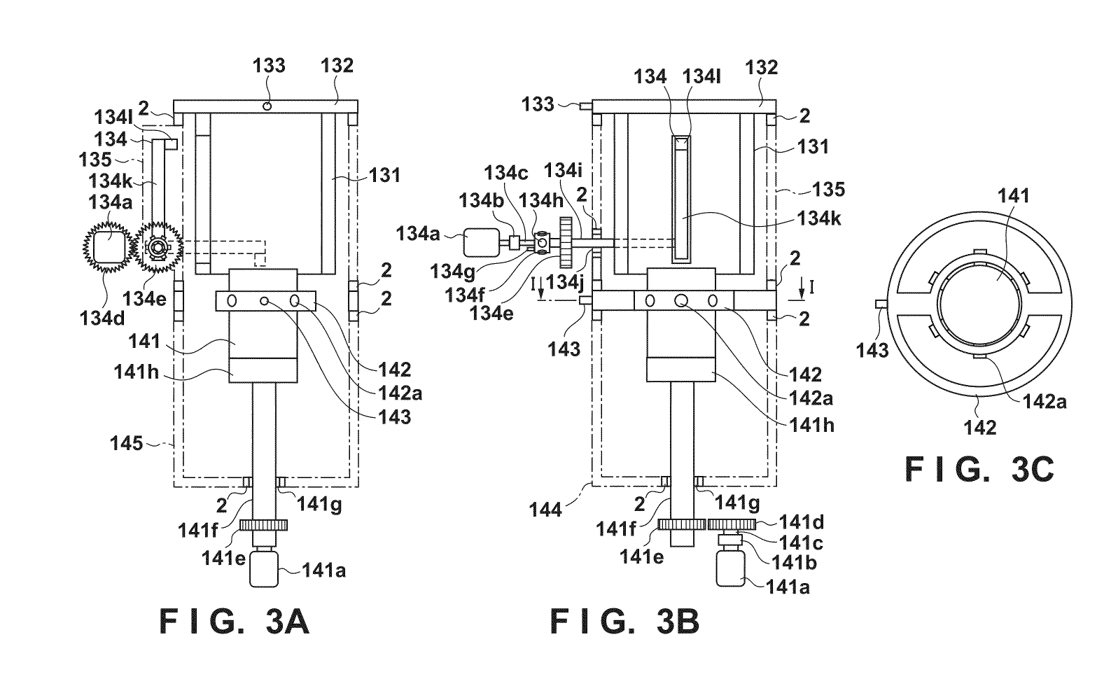

As shown in detail in FIGS. 3A to 3C, the anode unit 130 includes an anode 131, anode feeding unit 132, anode feeding terminal 133, striker 134, and anode housing 135.

The striker 134 comes into contact with the surface of the cathode target unit 140 at a predetermined timing to generate an arc discharge on the target surface. Electrons and target ions emitted from an arc spot on the cathode target unit 140 are converted into a plasma and guided to the process chamber 101. The cathode target unit 140 is also driven to rotate to a predetermined angle. Localization of an arc spot is prevented by relatively moving the position at which the striker 134 contacts the cathode target unit 140. Note that the arc spot is a location where an arc is generated on a target.

The striker 134 is set to the same potential as that of the anode 131. The insulating member 2 is interposed between the anode housing 135 and the anode feeding unit 132 to hold an electrically insulating state. The striker 134 is configured to be drivable by transmitting the driving force of a striker driving motor 134a via a striker driving motor coupling 134b, striker driving motor shaft 134c, striker driving motor gear 134d, striker driving motor power transmission gear 134e, and striker feeding/driving shaft 134i. A striker feeding terminal 134g, striker feeding unit 134f, and striker feeding brush 134h are connected to the striker feeding/driving shaft 134i. By arranging the striker feeding brush 134h in contact with the striker feeding/driving shaft, power can be fed to the striker 134. The insulating member 2 is interposed between the striker feeding/driving shaft 134i and the anode housing 135 to hold an electrically insulating state. In addition, a magnetic fluid 134j is interposed between the insulating member 2 and the striker feeding/driving shaft 134i. This structure makes it possible to drive the striker 134 and feed power without electrically connecting the striker feeding/driving shaft 134i and anode housing 135.

The striker 134 is constituted by an arm unit 134k and chip unit 134l, and is desirably made of a material that is durable at a high temperature and large current. For example, the arm unit 134k is made of molybdenum, and the chip unit 134l is made of graphite. The arm unit and chip unit may be integrated.

The cathode target unit 140 includes a cylindrical or disk-like carbon graphite cathode target 141, cathode target feeding unit 142, cathode target feeding terminal 143, and cathode target housing 144. The cathode target 141 is configured to be rotatable by transmitting the driving force of a cathode target rotation motor 141a via a cathode target rotation motor coupling 141b, cathode target rotation motor shaft 141c, cathode target rotation motor gear 141d, cathode target rotation motor power transmission gear 141e, cathode target rotation shaft 141f, and cathode target bracket 141h. Also, the cathode target 141 is configured to receive power by connecting it to the cathode target feeding unit 142, a cathode target feeding brush 142a, and the cathode target feeding terminal 143. Further, the insulating member 2 is interposed between the cathode target rotation shaft 141f and the cathode target housing 144 to hold an electrically insulating state. In addition, a magnetic fluid 141g is interposed between the insulating member 2 and the cathode target rotation shaft 141f. This structure makes it possible to rotate the cathode target 141 and feed power without electrically connecting the cathode target rotation shaft 141f and cathode target housing 144.

In the above-described arrangement, when the striker 134 and cathode target 141 contact each other, the anode 131 and cathode target 141 are short-circuited to generate an arc.

A negative voltage is applied from an arc power source (not shown) to the cathode target 141, and a positive voltage is applied to the striker 134 and anode 131, thereby forming a flow of electrons between the cathode target 141 and the anode 131 along a magnetic field generated by the anode coil 131a.

Electrons generated at the arc spot serve as arc maintenance electrons and ion transport electrons. The arc maintenance electrons are electrons which are obtained by guiding some of electrons generated on the target surface by the magnetic field of the anode coil 131a, and flow into the anode 131. The arc maintenance electrons are used to heat an arc spot by supplying a current between the cathode target 141 and the anode 131 in order to maintain a plasma arc generated at the cathode target 141.

The ion transport electrons are electrons for causing target ions to reach the substrate 1, and attract ions by using the Coulomb force of electrons. The ion transport electrons are guided toward the substrate 1 by a magnetic field generated by the filter unit 110.

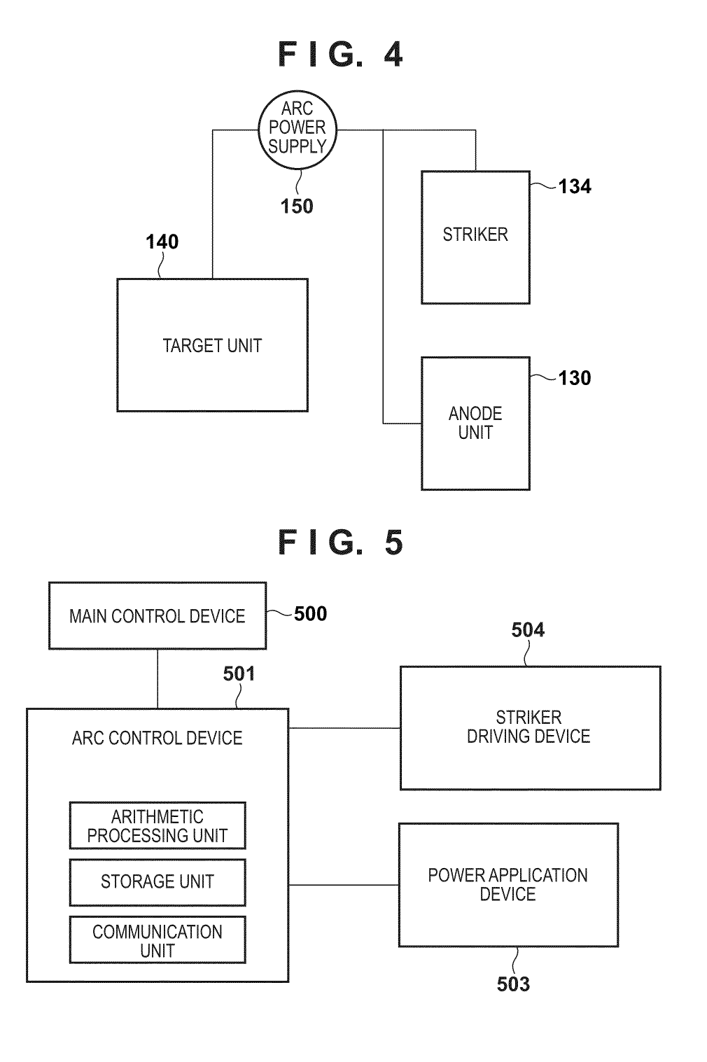

With the above-described arrangement, target ions are attached to and stacked on the surface of the substrate 1 inside the process chamber 101, thereby depositing a protection film.

<Power Supply System> The arrangement of the power supply system of the film deposition apparatus according to the embodiment will be described with reference to even FIG. 4.

The process chamber 101 is grounded. The filter unit 110 is connected to a filter power supply or current measurement unit (not shown) via the voltage application terminal 113. The anode unit 130 is connected to an arc power supply 150 via the anode feeding terminal 133. The striker 134 is connected to the arc power supply 150 via the striker feeding terminal 134g. The cathode target unit 140 is connected to the negative electrode side of the arc power supply 150 via the cathode target feeding terminal 143. The anode unit 130 and striker 134 are connected to the positive side of the arc power supply 150 to have the same potential. The cathode target unit 140 is connected to the negative side of the arc power supply 150. The arc power supply 150 is desirably of a current supply control type, but may be of a voltage application control type. In this embodiment, a current and voltage will be generically called power herein.

Note that the circuit may be constituted using a plurality of power supplies because a circuit configured to generate a potential difference between the anode unit 130 and the cathode target unit 140 generates an arc discharge between the anode unit 130 and the cathode target unit 140. An example is a circuit in which one terminal of the first power supply is grounded, its other terminal is connected to the anode unit 130, one terminal of the second power supply is connected to the cathode target unit 140, and its other terminal is grounded.

The striker 134 according to the embodiment is connected to the arc power supply 150 parallel to the anode unit 130. However, series wiring of connecting the striker 134 to the anode unit 130 is also possible. If powers supplied to the striker 134 and anode unit 130 are substantially the same, a power supply for supplying power to the striker 134 and a power supply source for supplying power to the anode unit 130 may be separate. The embodiment assumes that when power is supplied to the anode unit 130 in generating an arc, power is similarly supplied to even the striker 134.

<Control System> The schematic arrangement of the control system of the film deposition apparatus according to the embodiment will be described with reference to FIG. 5.

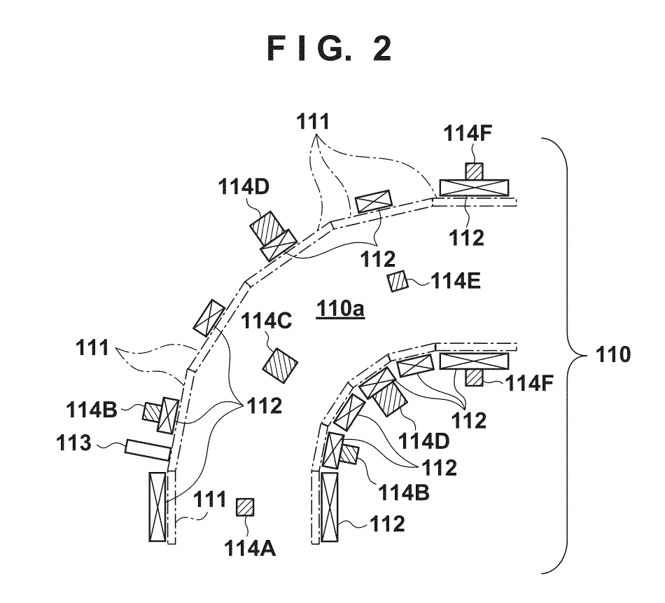

As shown in FIG. 5, the film deposition apparatus according to the embodiment includes a main control device 500 which comprehensively controls the overall apparatus, and an arc control device 501 which controls generation of an arc. The main control device 500 and arc control device 501 include a storage unit such as a memory, an arithmetic processing unit such as a CPU, and a communication unit. The arc control device 501 controls power supply by the arc power supply 150 serving as a power application device 503 in accordance with a control signal received from the main control device 500. In addition, the arc control device 501 controls rotation of the motors 134a and 141a serving as a striker driving device 504. Note that the power application device 503 includes a resistance meter for measuring a resistance value between the striker 134 and the cathode target unit 140. The striker driving device 504 also includes a sensor, such as an encoder, which detects the rotational speed and torque of the striker driving motor 134a and those of the cathode target rotation motor 141a of the cathode target unit 140.

<Permanent Magnet of Filter Unit> Next, the arrangement and function of the permanent magnets of the filter unit in the film deposition apparatus according to the embodiment will be explained with reference to FIGS. 2, 6, and 7A to 7C.

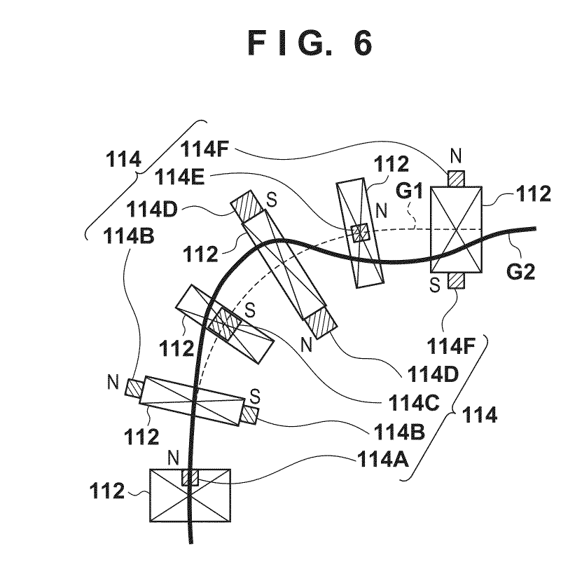

FIG. 6 shows the arrangement of the permanent magnets of the filter unit according to the embodiment.

As shown in FIGS. 2 and 6, the filter coils 112, and six permanent magnet pairs 114A to 114F are arranged on the transport pipe 111 according to the embodiment. Each of the permanent magnet pairs 114A to 114F generates a magnetic field in a direction perpendicular to the direction of a magnetic field generated by the filter coil 112, and is formed from two paired permanent magnets so that opposite polarities face each other. The permanent magnet pairs 114A to 114F are arranged by rotating every other pair by 90° in the same direction using, as the central axis, a direction G1 of a magnetic field generated by the filter coil 112. Although a samarium-based magnet is applied as the permanent magnet in the embodiment, a ferrite- or neodymium-based magnet is also usable.

In the embodiment, the volume of each of the two permanent magnet pairs 114C and 114D at the center is set to be double the volume of each of the four remaining permanent magnet pairs 114A, 114B, 114E, and 114F, out of the six permanent magnet pairs 114A to 114F, so that a synthetic magnetic field G2 of the filter coil 112 and permanent magnet 114 becomes a helical magnetic field as symmetrical as possible with respect to the central axis G1 of the coil. By doubling the volumes of permanent magnets of the same type, the magnetic force is doubled.

The magnetic force is doubled to make helical a plasma path formed by the phase magnetic field G1 and the magnetic field G2 obtained by synthesizing two magnetic fields generated by the permanent magnets. More specifically, the plasma path is made helical by bending lines of magnetic force by the two, first and second permanent magnet pairs 114A and 114B, and bending them by double force by the two, third and fourth permanent magnet pairs 114C and 114D in a direction opposite to that of the first and second pairs.

Since the permanent magnets 114 are arranged with respect to the filter coils 112 in this manner, the magnetic field G1 generated by the coils 112, and the synthetic magnetic field G2 of magnetic fields generated by the permanent magnets 114 can be formed to bend lines of magnetic force, as represented by the magnetic field G2 in FIG. 6. If the magnetic field strengths and orientations of the coils 112 and permanent magnets 114 are known, the angle of the magnetic field by the synthetic magnetic field G2 is given by:

θ=tan⁻¹(Bm/Bc) (1)

where Bm is the magnetic field strength of the permanent magnet, and Bc is the magnetic field strength of the electromagnet. From equation (1), the number of turns of the coil, its current, and the size and arrangement of the permanent magnet can be obtained.

This result reveals that the permanent magnet 114 influences the line G1 of magnetic force of the coil 112 to bend the line G1 of magnetic force of the coil. Further, electrons and ions in a plasma move along lines of magnetic force while holding a Larmor radius determined by their energies and weights with respect to lines of magnetic force. When helical lines of magnetic force as shown in FIG. 6 are generated, the plasma path also becomes helical, similar to the line G2 of magnetic force.

This is applied to vacuum arc deposition. When a plasma generated in the arc discharge unit (the surface of the cathode target unit 140) flies close to the permanent magnet pair 114A of the filter unit 110, the plasma path is also bent along bent lines of magnetic force. At this time, centrifugal force acts on electrons, ions, and droplets in the plasma, shaking them off the plasma in at a ratio of electron<ion<droplet based on a physical law formula regarding centrifugal force: F=mv2/r.

In this manner, the plasma passes through the filter unit 110 in which a helical plasma path is formed by the permanent magnets 114. The number of droplets in the plasma becomes relatively small, reducing particles in a film stacked on a material to be deposited. By using the filter unit 110 in which the permanent magnets 114 are arranged, as in the embodiment, the filter unit 110 need not be bent twice or more, greatly improving the maintainability. Since the particle removal method of applying a voltage to the filter unit 110 to capture droplets need not be employed, neither a device nor power supply for supplying power to the filter unit 110 need be used, and the cost can therefore be reduced.

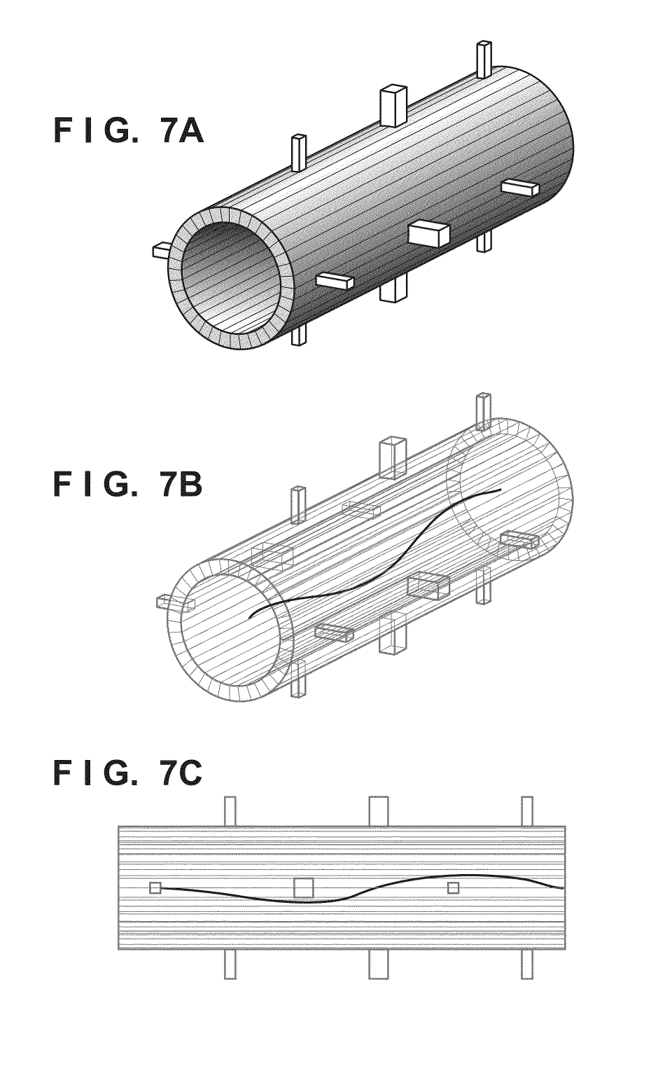

FIGS. 7A to 7C show a simple magnetic field simulation result of the filter unit according to the embodiment.

The filter unit 110 according to the embodiment has a shape obtained by bending a linear filter unit shown in FIGS. 7A to 7C directly at 90°.

As described above, according to the embodiment, droplets in a plasma can be removed by the helical magnetic field G2 of the filter unit 110. A plasma containing less droplets can reach a material to be deposited. Particles in a film stacked on the material to be deposited can be reduced, and the maintainability can be improved.

Note that the magnet which bends the plasma path according to the embodiment may be constituted by an electromagnet instead of a permanent magnet, or a combination of a permanent magnet and electromagnet. When an electromagnet is used, a plasma which less changes can be obtained by adjusting the application power in accordance with the progress of erosion of the cathode target unit 140.

Although the embodiment uses six pairs of permanent magnets, a combination of magnets can be changed as long as a helical magnetic field can be formed. For example, many permanent magnets may be helically arrayed around the outer surface of the filter unit while rotating them clockwise or counterclockwise by 90°. In this case, the number of times of bending can be adjusted in accordance with the number of magnets.

Note that the effects of the embodiment are not limited to a helical magnetic field. Even when a meandering magnetic field is generated, the same effects as those described above can be obtained. As magnets when generating a meandering magnetic field, at least three pairs of permanent magnets are arranged while rotating each pair at 180°.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-200493, filed Sep. 26, 2013 which is hereby incorporated by reference herein in its entirety.

What is claimed is:

1. A deposition apparatus comprising:
a source unit having a function of generating a plasma by an arc discharge; and
a filter unit configured to transport the plasma generated by the source unit toward a material to be deposited,
wherein the filter unit includes a duct configured to transport the plasma, a magnetic field formation unit configured to form, in the duct, a magnetic field for transporting the plasma, and a magnetic field bending unit configured to generate a magnetic force for bending the magnetic field formed by the magnetic field formation unit.

2. The apparatus according to claim 1, wherein the magnetic field bending unit generates a magnetic field perpendicularly crossing the magnetic field formed by the magnetic field formation unit.

3. The apparatus according to claim 1, wherein the magnetic field bending unit is formed from a permanent magnet or an electromagnet.

4. The apparatus according to claim 1, wherein the magnetic field bending unit helically forms a path of the plasma transported inside the duct.

5. The apparatus according to claim 4, wherein the magnetic field bending unit is formed from a plurality of pairs each of magnets having opposite polarities facing each other, and the magnets are arranged while rotating each pair at 90° in the same direction using, as a central axis, a line of magnetic force formed by the magnetic field formation unit.

6. The apparatus according to claim 1, wherein the magnetic field bending unit forms, in a meandering shape, a path of the plasma transported inside the duct.

7. The apparatus according to claim 6, wherein the magnetic field bending unit is constituted by arranging at least three pairs of permanent magnets while rotating each pair at 180°.
